(19) United States
(12) Patent Application Publication
(10) Pub. No.: US 2005/0226087 A1
(43) Pub. Date: Oct. 13, 2005

(54) Protocol structure to accelerate memory transmission

(76) Inventors: Kuo-Chang Wang, Hsin Chu City (TW); Ching-Hung Tseng, Hsin Chu City (TW)

Correspondence Address: Kuo-Chang Wang, P.O. BOX 7-820, TAIPEI, TW

(21) Appl. No.: 10/822,290

(22) Filed: Apr. 12, 2004

(51) Int. Cl. G11C 8/00; G06F 9/26

(52) U.S. Cl. 365/230.06

(57) ABSTRACT

The present invention provides a protocol structure to accelerate memory transmission, characterized in that an address memory unit is built in the front end of the memory, of which comprises several address buffers, and there is a pointing design between each address buffer and the corresponding data block in the memory. Address data is saved in address buffers in advance by external pins to further quickly match such address data with the corresponding data block without entering long data address every time. The invention provides the industry users the method to rapidly change the data address for data transmission and access.

### BACKGROUND OF THE INVENTION

As to general electronic applications, external memories are often used to access data, and vendors also design memory cards with different specifications for the consumer market so as to meet customer requirement for data access space. However, while such memory needs several controls and data pins to transmit data, using too many or too few pins will slow down the data transmission so that if the memory address pointing requires to change often, and it will be a hideous process to reenter and change the long address to ensure a successful data access. Consequently, the access speed will become slow, and affect many peripheral applications.

### SUMMARY OF THE INVENTION

The primary objective of the present invention is to provide a protocol structure to accelerate memory transmission, characterized in that an address memory unit is built in the front end of the memory, of which comprises several address buffers, and provides external pin to input data address in advance.

The secondary objective of the present invention is to provide a protocol structure to accelerate memory transmission, characterized in that there is the pointing design between each memory buffers and the corresponding data block in the memory. Address data is saved in address buffers in advance by external pins to further quickly match such address data with the corresponding data block without entering long data address so to provide the method to rapidly change the data address for data transmission and access.

Another objective of the present invention is to provide the isolation pad of a conductive glass with new structure, of which can fix and mix with specifications, indicating that each address buffers could provide the external pins to input address data in advance without entering long data address every time. The invention provides the industry users the method to rapidly change the data address for data transmission and access.

### BRIEF DESCRIPTION OF THE DRAWINGS

FIG. 1 is the illustration of the invention in the block diagram;

FIG. 2 is the illustration of the invention by demonstrating an example with a better flow chart;

FIG. 3 is the illustration demonstrating how the pointing design looks like between address buffers and the corresponding data blocks.

### DETAILED DESCRIPTION OF THE PREFERRED EMBODIMENT

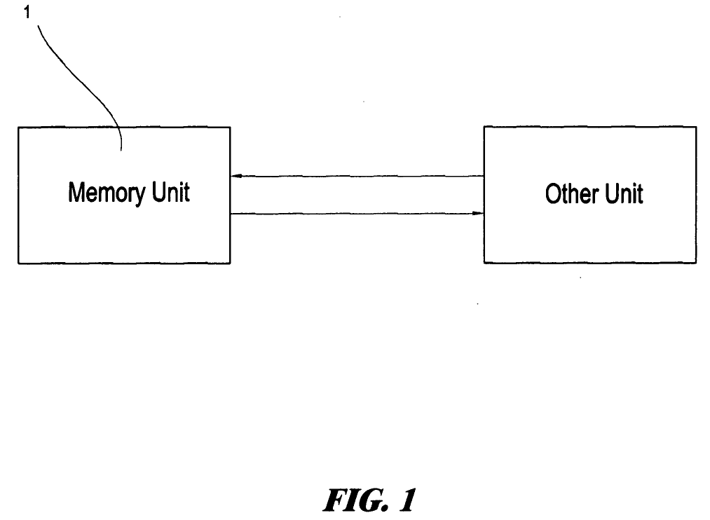

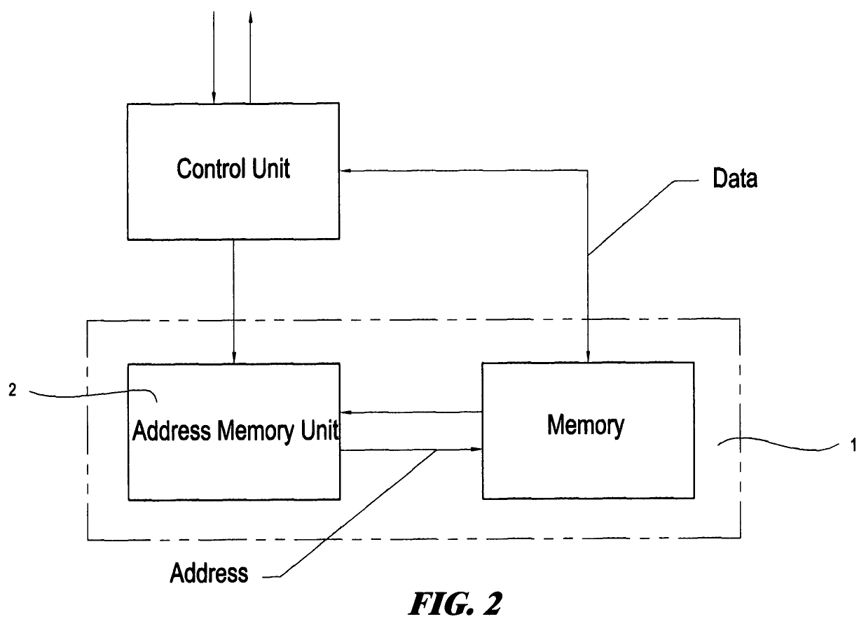

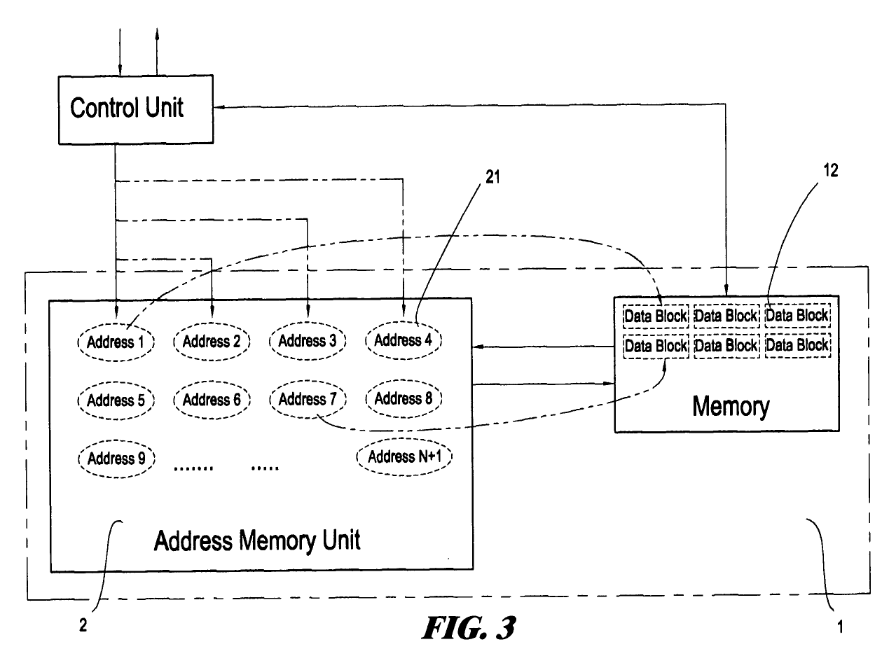

Please refer to FIGS. 1 to 3. The invention is a protocol structure to accelerate memory transmission, indicating that in front of memory 1 there is an in-built memory address unit 2, and such unit comprises several address buffers 21. There is a pointing design between each address buffer and the corresponding data block 12, which is the characteristic of the invention. Please refer to FIG. 3. The invention will save the address data into address buffers 21 in advance by the external pins and further to select quickly the corresponding data block 12 that an address buffer points to so as to rapidly change the data address for data transmission and access.

The invention has the characteristic to significantly reduce the transmission time when changing the memory address without inputting long data address every time so as to enhance industry applications, which in comparison is much better than that of a single memory.

While the present invention has been described in connection with what is considered the most practical and preferred embodiment, it is understood that the invention is not limited to the disclosed embodiments but is intended to cover various arrangements included within the spirit and scope of the broadest interpretation and equivalent arrangements.

1. A protocol structure to accelerate memory transmission, and the features including: a built-in address memory unit located in front end of the memory, of which comprises several address buffers, and there is a pointing design between each address buffer and the corresponding data block in the memory;
The several address buffers located in the aforementioned memory address unit provide the external pins to enter address data in advance and further to select quickly the corresponding data block that an address buffer points to so as to rapidly change the data address for data transmission and access.
